(19) United States
(12) Patent Application Publication
(10) Pub. No.: US 2023/0014146 A1
(43) Pub. Date: Jan. 19, 2023

(54) FILM DEPOSITION DEVICE AND SUBSTRATE SUPPORT DEVICE

(71) Applicant: Kioxia Corporation, Tokyo (JP)

(72) Inventor: Rikyu IKARIYAMA, Chigasaki (JP)

(73) Assignee: Kioxia Corporation, Tokyo (JP)

(21) Appl. No.: 17/643,064

(22) Filed: Dec. 7, 2021

(30) Foreign Application Priority Data
Jul. 19, 2021 (JP) 2021-119069

(51) Int. Cl. C23C 16/458; C23C 16/455; C23C 16/46; C23C 16/40

(52) U.S. Cl. CPC C23C 16/4583; C23C 16/45544; C23C 16/46; C23C 16/45563; C23C 16/40

(57) ABSTRACT

A film deposition device according to the present embodiment includes a chamber. A mounting part is provided in the chamber to allow a substrate to be placed thereon and contains aluminum nitride. A heater is provided in the mounting part. A supply part is configured to supply a process gas for film deposition to the substrate on the mounting part in the chamber. A cover film covers a mounting surface of the mounting part on which the substrate is placed, a back surface opposite to the mounting surface, and a side surface between the mounting surface and the back surface and contains yttrium oxide.

### CROSS REFERENCE TO RELATED APPLICATIONS

This application is based upon and claims the benefit of priority from the prior Japanese Patent Application No. 2021-119069, filed on Jul. 19, 2021, the entire contents of which are incorporated herein by reference.

### FIELD

The embodiments of the present invention relate to a film deposition device and substrate support device.

### BACKGROUND

A film deposition device, such as a CVD (Chemical Vapor Deposition) device, cleans a film and particles that have adhered to the inner wall of a chamber or a stage in film deposition, by using fluorine radicals. Meanwhile, the stage may be etched by the fluorine radicals to cause fluoride to adhere to a shower head of a process gas in such a cleaning process. When the fluoride is deposited on the shower head, the film deposition performance in film deposition is deteriorated, causing deterioration of in-plane uniformity of a deposited film.

The fluoride that has adhered to the shower head is difficult to remove, and it is therefore necessary to regularly replace the shower head itself with a new one. This shower head replacement increases the cost.

### BRIEF DESCRIPTION OF THE DRAWINGS

FIG. 1 is a cross-sectional view illustrating a configuration example of a film deposition device according to a first embodiment;

FIG. 2 is a cross-sectional view illustrating a configuration example of the stage according to the first embodiment;

FIG. 3A is a graph representing a spectrum intensity peak ratio of a material of the cover film to that of a material of the mounting part;

FIG. 3B is a graph illustrating a relation between the peak ratio and the number of particles;

FIG. 3C is a graph illustrating a relation between the peak ratio and a rate of mass change by cleaning;

FIG. 4A is a graph representing a spectrum intensity peak ratio of the material of the cover film to that of the material of the mounting part;

FIG. 4B is a graph illustrating a relation between the peak ratio and the number of particles;

FIG. 4C is a graph illustrating a relation between the peak ratio and a rate of mass change by cleaning;

FIG. 5 is a cross-sectional view illustrating a configuration example of the stage according to a second embodiment; and

FIG. 6 is a partial cross-sectional view illustrating an example of the mounting surface of the stage in detail.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A film deposition device according to the present embodiment includes a chamber. A mounting part is provided in the chamber to allow a substrate to be placed thereon and contains aluminum nitride. A heater is provided in the mounting part. A supply part is configured to supply a process gas for film deposition to the substrate on the mounting part in the chamber. A cover film covers a mounting surface of the mounting part on which the substrate is placed, a back surface opposite to the mounting surface, and a side surface between the mounting surface and the back surface and contains yttrium oxide.

### First Embodiment

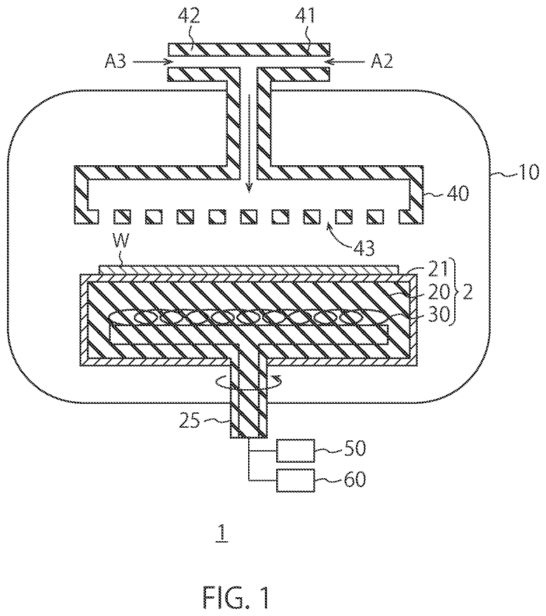

FIG. 1 is a cross-sectional view illustrating a configuration example of a film deposition device 1 according to a first embodiment. The film deposition device 1 is, for example, a plasma CVD device or a thermal CVD device and uses a halogen gas containing fluorine in a process of cleaning inside of a chamber 10.

The film deposition device 1 includes the chamber 10, a mounting part 20, a cover film 21, a heater 30, a shower head 40, a driver part 50, and a controller 60. In a case where the film deposition device 1 is a plasma CVD device, the film deposition device 1 may further include a high-frequency applying electrode, an RF power supply, a matching box, and the like (not illustrated).

The chamber 10 is a hollow case. The pressure in the chamber 10 can be reduced by evacuation. A metal material, for example, aluminum is used for the chamber 10.

The mounting part 20 is provided in the chamber 10. A semiconductor substrate W can be placed on the mounting part 20. The mounting part 20 sucks the semiconductor substrate W by vacuum or electrostatically attracts the semiconductor substrate W, and can turn about a shaft 25 by a driving force from the driver part 50. Aluminum nitride is mainly used for the mounting part 20.

A surface of the mounting part 20 is covered with the cover film 21. Yttrium oxide is used for the cover film 21.

The heater 30 is provided in the mounting part 20 and can heat the mounting part 20 and the semiconductor substrate W on the mounting part 20 to a temperature of 400° C. or more by being controlled by the controller 60 and receiving power supply. The heater 30 may be, for example, an electric heating coil such as nichrome wire.

The mounting part 20 and the heater 30 are sintered as one unit. The stage 2 is configured by covering the mounting part 20 with the covering film 21. The detailed configuration of the stage 2 will be described later.

The shower head 40 is a hollow member provided with a plurality of openings 43. The openings 43 of the shower head 40 are arranged to be opposed to the stage 2 in such a manner that a gas can be supplied toward the stage 2. The shower head 40 supplies a process gas for film deposition or a cleaning gas for cleaning into the chamber 10. A pipe 41 for supplying the process gas and a pipe 42 for supplying the cleaning gas are connected to the shower head 40.

The pipe 41 supplies the process gas to the shower head 40 as illustrated by an arrow A2, when film deposition is performed on the semiconductor substrate W. In this manner, the process gas is supplied to the semiconductor substrate W on the stage 2 through the openings 43 of the shower head 40. The process gas is, for example, TEOS (TetraEthOxySilane), silane (SiH₄), tungsten fluoride (WF₆), O₂ or N₂O as an oxidant, or N₂ or NH₃ as a nitriding agent and is used for forming a silicon oxide film, a silicon nitride film, or a metal film such as a tungsten film on the semiconductor substrate W.

The pipe 42 supplies the cleaning gas to the shower head 40 as illustrated by an arrow A3, when the inside of the chamber 10 is cleaned after film deposition. In this manner, the cleaning gas is supplied into the chamber 10 through the openings 43 of the shower head 40. The cleaning gas is, for example, fluorine radicals and is used for cleaning the inner wall of the chamber 10 and the stage 2.

The driver part 50 drives the stage 2 to turn about the shaft 25. The controller 60 controls power supply to the heater 30 and/or the driver part 50.

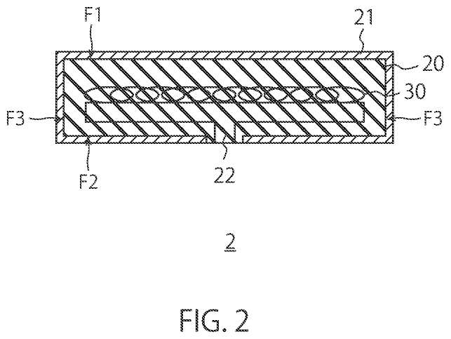

FIG. 2 is a cross-sectional view illustrating a configuration example of the stage 2 according to the first embodiment. The stage 2 as a substrate support device includes the mounting part 20, the cover film 21, the heater 30, and a connector 22.

The mounting part 20 includes the entire heater 30 and is sintered together with the heater 30 as one unit, as described above. Therefore, the heater 30 is not exposed in the chamber 10. The mounting part 20 has a mounting surface F1 on which the semiconductor substrate W is placed, a back surface F2 opposite to the mounting surface F1, and a side surface F3 between the mounting surface F1 and the back surface F2. The mounting part 20 has, for example, a substantially circular shape larger than the external shape of the semiconductor substrate W as viewed from above the mounting surface F1. Further, as illustrated in FIG. 2, the mounting part 20 has, for example, a substantially square shape as viewed from the side of the side surface F3. That is, the mounting part 20 has a substantially cylindrical shape.

The cover film 21 covers the mounting surface F1, the back surface F2, and the side surface F3 of the mounting part 20. For example, the cover film 21 is made of a material containing yttrium oxide, such as Y₂O₃ or YOF. The cover film 21 covers almost the entire surface of the mounting part 20 except for at least the connector 22. The cover film 21 covers the mounting surface F1, the back surface F2, and the side surface F3 of the mounting part 20 with a substantially uniform thickness. The thickness of the cover film 21 is, for example, 0.5 μm or more and less than 10 μm.

The connector 22 is connected to the shaft 25 illustrated in FIG. 1. By connection of the connector 22 to the shaft 25, an electric heating coil of the heater 30 is connected to controller 60 via a heating wire of the shaft 25. Further, by connection of the connector 22 to the shaft 25, the mounting part 20 is connected to driver part 50 via the shaft 25 and becomes turnable. In the stage 2, the mounting part 20 and the shaft 25 may be sintered as one unit. In this case, the cover film 21 may cover up to the circumferential surface of the shaft 25.

### (Consideration on Cover Film 21)

In the film deposition device 1 employing plasma CVD, thermal CVD, or the like, fluorine radicals are introduced into the chamber 10 in a cleaning process after a film deposition process, and deposited materials or particles that have adhered to the inner wall of the chamber 10 or the stage 2 are etched in order to prevent dust generation in the film deposition process. In this manner, the inside of the chamber 10 is cleaned, so that dust generation in the next film deposition process is prevented.

When aluminum nitride of the mounting part 20 is exposed, the material of the mounting part 20 is etched by fluorine radicals in an atmosphere heated to about 400° C. or more in the cleaning process. The etched material of the mounting part 20 may adhere to the shower head 40 as aluminum fluoride. When aluminum fluoride is accumulated on the shower head 40, the in-plane uniformity of the thickness of a material film formed on the semiconductor substrate W is deteriorated in the film deposition process. Since aluminum fluoride that has adhered to the shower head 40 is difficult to remove, it is necessary to regularly replace the shower head with a new one in order to prevent deterioration of the film deposition performance.

Meanwhile, the mounting part 20 is covered with the cover film 21 in the present embodiment. The cover film 21 is made of yttrium oxide. Yttrium oxide is hard to etch by fluorine radicals even in an atmosphere heated to about 400° C. or more, as will be described later. It is therefore possible to prevent deposited materials such as aluminum fluoride from adhering to the shower head 40 in the cleaning process. As a result, it is possible to prevent deterioration of the film deposition performance in the film deposition process, thereby extending the life of the shower head 40. Fluorine radicals in the cleaning process clean the whole inside of the chamber 10 isotropically. Therefore, the cover film 21 covers the entire surface (the mounting surface F1, the back surface F2, and the side surface F3) of the mounting part 20 to avoid contact of the mounting part 20 with fluorine radicals as much as possible.

Examples of a method of forming the cover film 21 include ALD (Atomic Layer Deposition), MOCVD (Metal-Organic CVD), sputtering, and ion plating. Among those methods, ALD and MOCVD can deposit a Y₂O₃ film (an yttria film) or a YOF film (an yttrium oxyfluoride film) on the mounting part 20 isotropically. Therefore, according to ALD and MOCVD, it is possible to entirely form a Y₂O₃ film or a YOF film on the mounting surface F1, the back surface F2, and the side surface F3 of the mounting part 20 substantially uniformly.

Meanwhile, sputtering and ion plating deposit a Y₂O₃ film or a YOF film on the mounting part 20 anisotropically. That is, according to sputtering and ion plating, it is difficult to form a Y₂O₃ film or a YOF film on the entire surface of the mounting part 20 uniformly.

Therefore, it can be said that ALD and MOCVD are preferable in order to form a Y₂O₃ film or a YOF film on the entire surface of the mounting part 20 substantially uniformly. When ALD and MOCVD are compared with each other, a Y₂O₃ film or a YOF film formed by MOCVD is inferior in crystallinity to a Y₂O₃ film or a YOF film formed by ALD and has more particles, as will be described later.

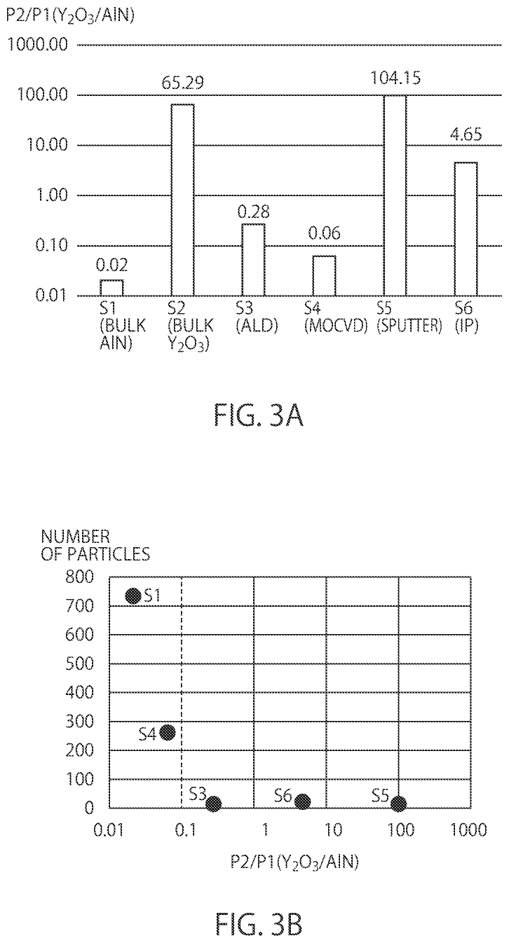

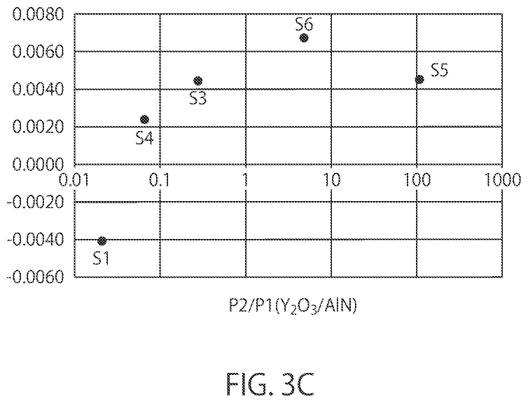

FIG. 3A is a graph representing a spectrum intensity peak ratio of a material of the cover film 21 to that of a material of the mounting part 20. The material of the mounting part 20 is, for example, aluminum nitride (AlN), and the material of the cover film 21 is, for example, yttria (Y₂O₃).

The horizontal axis of this graph represents materials of samples S1 to S6. The sample S1 is a simple substance of aluminum nitride (bulk AlN). The sample S2 is a simple substance of yttria (bulk Y₂O₃). The sample S3 is the cover film 21 (a Y₂O₃ film) formed on the mounting part 20 (AlN) by ALD. The sample S4 is the cover film 21 (a Y₂O₃ film) formed on the mounting part 20 (AlN) by MOCVD. The sample S5 is the cover film 21 (a Y₂O₃ film) formed on the mounting part 20 by sputtering. The sample S6 is the cover film 21 (a Y₂O₃ film) formed on the mounting part 20 by ion plating.

The vertical axis represents a value of a ratio P2/P1 (hereinafter also “peak ratio P2/P1”) of an intensity peak P2 (2θ=29.15°) of an X-ray diffraction spectrum of yttria (Y₂O₃) as the material of the cover film 21 to an intensity peak P1 (2θ=33.24°) of an X-ray diffraction spectrum of aluminum nitride (AlN) as the material of the mounting part 20.

Since the sample S1 is a simple substance of aluminum nitride, almost no yttria is detected, and the peak ratio P2/P1 is very small and close to zero. Since the sample S2 is a simple substance of yttria, much yttria is detected contrary to the sample S1, and the peak ratio P2/P1 is very large. The samples S1 and S2 are represented in the graph as reference values.

When the samples S3 to S6 are compared with one another, the peak ratios P2/P1 of the samples S5 and S6 are very large as compared with those of the samples S3 and S4. This is because the yttria films respectively formed by sputtering and ion plating are thicker than the yttria films respectively formed by ALD and MOCVD.

When the samples S3 and S4 are compared with each other, the yttria films having substantially the same thickness are formed by ALD and MOCVD, respectively. However, the peak ratio P2/P1 of the sample S4 is smaller than that of the sample S3. The yttria film formed by MOCVD is lower in crystallinity than the yttria film formed by ALD. Accordingly, the spectrum intensity of the yttria film formed by MOCVD is lower than that of the yttria film formed by ALD. Therefore, the peak ratio P2/P1 of the sample S4 by MOCVD is smaller than that of the sample S3 by ALD.

FIG. 3B is a graph illustrating a relation between the peak ratio P2/P1 and the number of particles. The horizontal axis of this graph represents the peak ratio P2/P1. The vertical axis represents the number of particles on a surface of each of the samples S1 and S3 to S6 after a cleaning process.

It is found from this graph that the number of particles is almost zero when the peak ratio P2/P1 is 0.1 or more, and becomes larger when the peak ratio P2/P1 is less than 0.1. Therefore, it is preferable that the peak ratio P2/P1 is 0.1 or more. For example, the number of particles is large in the samples S1 and S4 for which the peak ratio P2/P1 is less than 0.1 as represented in FIG. 3A. That is, it is found that the bulk AlN and the yttria film formed by MOCVD have many particles. This is because crystallinity of the yttria film formed by MOCVD is low.

Meanwhile, the yttria film formed by ALD as the sample S3 is isotropically formed on the entire surface of the mounting part 20 and has a small number of particles. Therefore, the yttria film formed by ALD is preferable as the cover film 21.

On the other hand, the yttria film formed by ALD is thinner than the yttria films respectively formed by sputtering and ion plating. This is because the deposition rate in ALD is slower than those in sputtering and ion plating. Therefore, ALD takes more time and higher cost for forming a thick yttria film. For example, ALD takes very long time and cost to form an yttria film having a thickness exceeding 1 μm. It is therefore preferable that the thickness of the yttria film formed by ALD is 1 μm or less.

FIG. 3C is a graph illustrating a relation between the peak ratio P2/P1 and a rate of mass change by cleaning. The horizontal axis of this graph represents the peak ratio P2/P1. The vertical axis represents a mass change rate of the stage 2 before and after a cleaning process. On the vertical axis, zero means that the mass of the stage 2 was not changed before and after the cleaning process and the stage 2 was not etched by fluorine radicals in the cleaning process. The graph shows the results for the samples S1 and S3 to S6. The result for the sample S2 that is a simple substance of yttria is also omitted in this graph. Identical results were obtained also when the temperature in the cleaning process was changed.

According to this graph, bulk AlN as the sample S1 was etched by fluorine radicals, and the mass of the stage 2 was reduced. Etched AlN adheres to the shower head 40 as aluminum fluoride.

For the samples S3 to S6 other than the sample S1, the mass of the stage 2 was not reduced but was increased. It is considered that the increase is because the mounting part 20 or the cover film 21 of the stage 2 was almost not etched by fluorine radicals in the samples S3 to S6 and instead other deposited materials from outside adhered to the stage 2. Therefore, it is found that the stage 2 having the mounting part 20 covered with an yttria film is not etched in a cleaning process and can prevent accumulation of aluminum fluoride on the shower head 40.

As described above, according to the present embodiment, generation of particles on the stage 2 can be prevented by the peak ratio P2/P1 being 0.1 or more. A film deposition method that can achieve the peak ratio P2/P1 of 0.1 or more is ALD (S3), sputtering (S5), and ion plating (S6) illustrated in FIG. 3A. Further, ALD that can perform isotropic film deposition is preferable in order to cover the entire surface of the mounting part 20.

Since ALD has a slower deposition rate as compared with sputtering or ion plating, the cover film 21 is preferably as thin as possible while preventing the mounting part 20 from being etched. For example, it is preferable that the thickness of the cover film 21 is 0.5 μm or more and less than 10 μm. The cover film 21 can protect aluminum nitride in the mounting part 20 against fluorine radicals in a cleaning process and prevent the mounting part 20 from being etched, due to having a thickness of 0.5 μm or more. Further, the thickness of the cover film 21 is preferably less than 10 μm and more preferably 1 μm or less, considering the manufacturing time and the manufacturing cost of ALD.

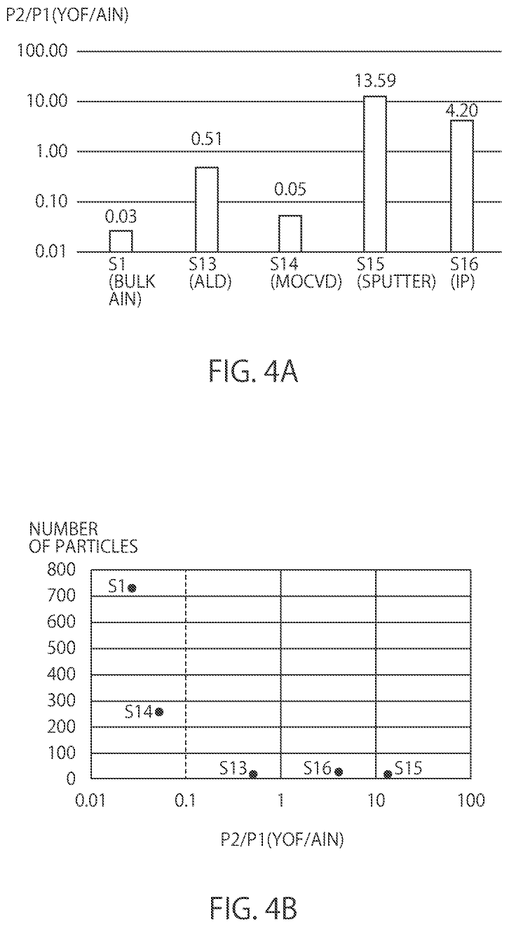

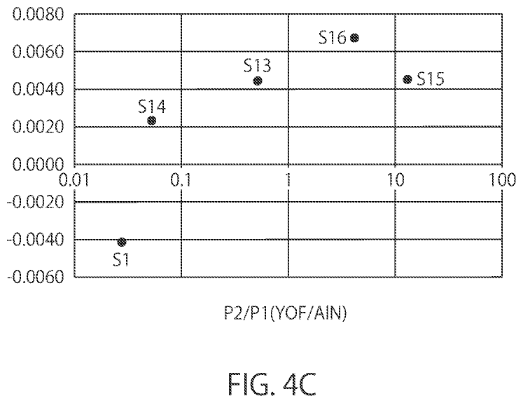

Next, a case where the cover film 21 is an yttrium oxyfluoride (YOF) film is described with reference to FIGS. 4A to 4C. The example illustrated in FIGS. 4A to 4C is different from the example illustrated in FIGS. 3A to 3C in that the material of the cover film 21 is yttrium oxyfluoride (YOF). When an yttria film is exposed to fluorine radicals in a cleaning process, most of the film becomes an yttrium oxyfluoride (YOF) film. Therefore, the cover film 21 illustrated in FIGS. 3A to 3C changes from an yttria film to a YOF film through the cleaning process. The results shown in FIGS. 4A to 4C are identical also for such a YOF film changed from an yttria film.

FIG. 4A is a graph representing a spectrum intensity peak ratio of the material of the cover film 21 to that of the material of the mounting part 20. The peak ratio for a simple substance of yttrium oxyfluoride is omitted in this graph.

The horizontal axis in the graph in FIG. 4A represents materials in the sample S1 and samples S13 to S16. The sample S1 is bulk AlN as described above. The sample S13 is a YOF film formed on the mounting part 20 (AlN) by ALD or a YOF film obtained by fluorinating an yttria film formed by ALD. The sample S14 is a YOF film formed on the mounting part 20 (AlN) by MOCVD or a YOF film obtained by fluorinating an yttria film formed by MOCVD. The sample S15 is a YOF film formed on the mounting part 20 by sputtering or a YOF film obtained by fluorinating an yttria film formed by sputtering. The sample S16 is a YOF film formed on the mounting part 20 by ion plating or a YOF film obtained by fluorinating an yttria film formed by ion plating.

The vertical axis in the graph in FIG. 4A represents a value of the ratio P2/P1 of the intensity peak P2 (2θ=28.064°) of an X-ray diffraction spectrum of the material (YOF) of the cover film 21 to the intensity peak P1 (2θ=33.24°) of an X-ray diffraction spectrum of the material (AlN) of the mounting part 20, similarly to the vertical axis in FIG. 3A. The samples S13 to S16 have similar characteristics to those of the samples S3 to S6, respectively. Therefore, the peak ratio P2/P1 of the sample S14 by MOCVD is smaller than that of the sample S13 by ALD.

FIG. 4B is a graph illustrating a relation between the peak ratio P2/P1 and the number of particles. The samples S13 to S16 have identical characteristics to those of the samples S3 to S6, respectively, also in this graph. That is, it is found that the number of particles is almost zero when the peak ratio P2/P1 is 0.1 or more, and becomes larger when the peak ratio P2/P1 is less than 0.1. Therefore, it is preferable that the peak ratio P2/P1 is 0.1 or more.

As described above, a YOF film formed by ALD is isotropically formed on the entire surface of the mounting part 20 and has a small number of particles. Therefore, the YOF film formed by ALD is also preferable as the cover film 21, similarly to an yttria film formed by ALD. Meanwhile, it is found that a YOF film formed by MOCVD has a small peak ratio P2/P1 and has many particles.

The cover film 21 that is a YOF film can prevent the mounting part 20 from being etched by fluorine radicals in a cleaning process, due to having a thickness of 0.5 μm or more, similarly to an yttria film. Further, the thickness of the YOF film formed by ALD is also preferably less than 10 μm and more preferably 1 μm or less, considering the manufacturing time and the manufacturing cost of ALD, similarly to an yttria film formed by ALD.

FIG. 4C is a graph illustrating a relation between the peak ratio P2/P1 and a rate of mass change by cleaning. The samples S13 to S16 have identical characteristics to those of the samples S3 to S6, respectively, also in this graph. That is, bulk AlN as the sample S1 was etched by fluorine radicals, and the mass of the stage 2 was reduced.

For the samples S13 to S16 other than the sample S1, the mass of the stage 2 was not reduced but was increased. It is considered that the increase is because the mounting part 20 or the cover film 21 of the stage 2 was almost not etched by fluorine radicals in the samples S13 to S16. Therefore, it is found that the stage 2 having the mounting part 20 covered with a YOF film is not etched in a cleaning process and can prevent accumulation of aluminum fluoride on the shower head 40.

As described above, even though the cover film 21 is formed by a YOF film, generation of particles on the stage 2 can be prevented by the peak ratio P2/P1 being 0.1 or more. A film deposition method that can achieve the peak ratio P2/P1 of 0.1 or more is ALD (S13), sputtering (S15), and ion plating (S16) illustrated in FIG. 4A. Further, it can be said that ALD that is an isotropic film deposition method is preferable in order to cover the entire surface of the mounting part 20.

According to the present embodiment, the mounting part 20 is covered with the cover film 21. The cover film 21 covers the entire surface (the mounting surface F1, the back surface F2, and the side surface F3) of the mounting part 20. The cover film 21 is made of yttrium oxide. It is therefore possible to prevent deposited materials such as aluminum fluoride from adhering to the shower head 40 in a cleaning process. As a result, it is possible to prevent generation of particles in a film deposition process to prevent deterioration of the film deposition performance, thereby extending the life of the shower head 40. Therefore, it is possible to suppress the cost and prevent deterioration of the film deposition performance. Consequently, yield of a product is also improved.

### Second Embodiment

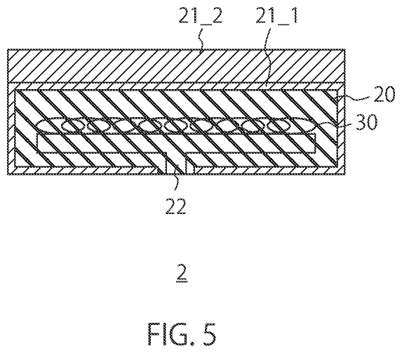

FIG. 5 is a cross-sectional view illustrating a configuration example of the stage 2 according to a second embodiment. In the second embodiment, a laminated film of a cover film 21_1 and a cover film 21_2 covers the mounting surface F1 of the mounting part 20. When a film deposition process for the semiconductor substrate W placed on the stage 2 is repeated, the mounting part 20 may be worn on the mounting surface F1 side by contact with the semiconductor substrate W, and a film covering the mounting surface F1 may become thin. Meanwhile, according to the present embodiment, the cover film 21_2 is stacked on the cover film 21_1 on the mounting surface F1 of the mounting part 20, and wear by contact with the semiconductor substrate W on the mounting surface F1 side of the mounting part 20 is prevented. The material for the cover film 21_1 is, for example, yttria (Y₂O₃), yttrium oxyfluoride (YOF), or yttrium fluoride (YF₃). The material for the cover film 21_2 is yttrium oxide, for example, yttria (Y₂O₃) or yttrium oxyfluoride (YOF).

The cover film 21_1 covers the entire surface, that is, the mounting surface F1, the back surface F2, and the side surface F3 of the mounting part 20. Therefore, the cover film 21_1 is formed by an isotropic film deposition method (ALD or MOCVD).

In the second embodiment, the cover film 21_2 is further provided on the cover film 21_1 covering the mounting surface F1. Therefore, when the cover film 21_2 has a small number of particles, use of the cover film 21_1 having more particles in the laminated film is not likely to be a problem in a film deposition process. For example, in a case where the cover film 21_1 is formed by MOCVD, the peak ratio P2/P1 becomes less than 0.1, and the particles are increased as compared with a case where the cover film 21_1 is formed by ALD, as described above. However, these particles are not a problem because the cover film 21_2 is stacked on the cover film 21_1 on the mounting surface F1. Meanwhile, it is assumed that the back surface F2 and the side surface F3 have more particles than the mounting surface F1 because the cover film 21_1 is exposed in these surfaces F2 and F3. However, the influence of the material that has been etched by fluorine radicals and has adhered to the shower head 40 on the film deposition performance is smaller than on the mounting surface F1 side that is opposed to the shower head 40. Further, the number of particles can be made smaller than in a case where the back surface F2 side and the side surface F3 side are not covered with the cover film 21_1 and therefore aluminum nitride in the mounting part 20 is directly exposed.

Since it suffices that the cover film 21_2 is formed on the cover film 21_1 on the mounting surface F1 side, the cover film 21_2 may be formed by an anisotropic film deposition method (for example, sputtering or ion plating). Because of a faster film deposition rate of sputtering and ion plating than ALD and MOCVD, the cover film 21_2 can be formed on the cover film 21_1 on the mounting surface F1 to be thicker than the cover film 21_1. The thickness of the cover film 21_1 is relatively thin, for example, 0.02 to 1 μm, and the thickness of the cover film 21_2 is relatively thick, for example, 1 to 24 μm. The total thickness of the cover films 21_1 and 21_2 is 1 to 25 μm. In this case, the ratio P2/P1 of the intensity peak of an X-ray diffraction spectrum may be larger on the mounting surface F1 side than on the back surface F2 side and the side surface F3 side so as to indicate values obtained by respective film deposition methods in FIGS. 3A and 4A.

The cover film 21_2 may be formed by ALD. That is, the cover film 21_2 may be formed by ALD in place of sputtering or ion plating on the cover film 21_1 formed by MOCVD. In this case, although the cover film 21_2 becomes thin, the cover film 21_2 formed by ALD covers the entire surface, that is, the mounting surface F1, the back surface F2, and the side surface F3 of the mounting part 20. Therefore, it is possible to prevent generation of particles on the cover film 21_1 on the back surface F2 and the side surface F3.

When an yttria (Y₂O₃) film or an yttrium oxyfluoride (YOF) film formed by MOCVD is exposed to fluorine radicals, most of the film becomes an yttrium fluoride (YF₃) film. Therefore, the cover film 21_1 formed by MOCVD can be modified into an yttrium fluoride film by coming into contact with fluorine radicals in a cleaning process, even if that cover film 21_1 is an yttria film or an yttrium oxyfluoride film in an initial stage of manufacturing.

When an yttria film formed by ALD, sputtering, or ion plating is exposed to fluorine radicals, most of the film becomes an yttrium oxyfluoride film. Therefore, most of the cover film 21_2 formed by sputtering or ion plating becomes an yttrium oxyfluoride film by being exposed to fluorine radicals, even if that cover film 21_2 is an yttria film or an yttrium oxyfluoride film in an initial stage of manufacturing. Further, most of the cover film 21_1 or 21_2 formed by ALD can be modified into an yttrium oxyfluoride film by coming into contact with fluorine radicals, even if that cover film 21_1 or 21_2 is an yttria film or an yttrium oxyfluoride film in an initial stage of manufacturing.

That is, the cover films 21_1 and 21_2 can become a laminated film of an yttria film, an yttrium oxyfluoride film, or an yttrium fluoride film and an yttria film or an yttrium oxyfluoride film.

Also in the second embodiment, the cover film 21_2 for which the ratio P2/P1 of the intensity peak of an X-ray diffraction spectrum is 0.1 or more is provided on at least the mounting surface F1 of the mounting part 20. Therefore, it is possible to prevent generation of particles on the stage 2. Further, the mounting part 20 can be prevented from being etched in a cleaning process, because the cover film 21_1 covers the entire surface of the mounting part 20.

Other configurations in the second embodiment may be identical to corresponding ones in the first embodiment. Therefore, the second embodiment can obtain effects identical to those of the first embodiment.

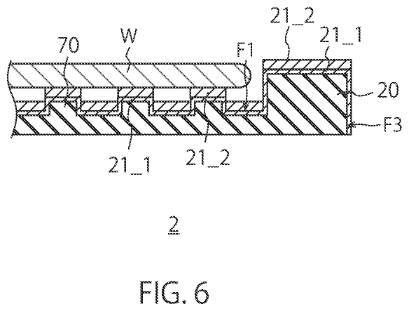

FIG. 6 is a partial cross-sectional view illustrating an example of the mounting surface F1 of the stage 2 in detail. In many cases, the mounting surface F1 of the mounting part 20 has a number of convex portions 70. That is, the mounting surface F1 is subjected to so-called embossing in many cases. The convex portions 70 project from the mounting surface F1 and support the semiconductor substrate W. The height of each of the convex portions 70 from the mounting surface F1 is 10 μm or more and 50 μm or less. When the semiconductor substrate W is released from a vacuum chuck or an electrostatic chuck after a film deposition process, the convex portions 70 separate the semiconductor substrate W sucked onto the mounting surface F1 from the mounting surface F1. Therefore, it is possible to make removal of the semiconductor substrate W from the mounting part 20 easy after the film deposition process.

FIG. 6 illustrates a case where the mounting surface F1 having those convex portions 70 is covered with the cover films 21_1 and 21_2 according to the second embodiment. Since the cover film 21_1 is deposited by an isotropic film deposition method (for example, ALD or MOCVD), it can cover the top surface and the side surface of each of the convex portions 70 substantially uniformly. Further, since the cover film 21_2 is deposited by an anisotropic film deposition method (for example, sputtering or ion plating), it can cover the top surface of each of the convex portions 70 thickly.

It is preferable that the cover film 21_1 has a thickness of 0.02 μm or more in order to protect the side surface of each of the convex portions 70. Further, the total thickness of the cover films 21_1 and 21_2 is preferably more than 1 μm when wear with time and thickness reduction of the cover films 21_1 and 21_2 caused by contact between the mounting surface F1 of the stage 2 and the semiconductor substrate W are considered, and is preferably 25 μm or less in order to prevent the convex portions 70 from being buried and allow the convex portions 70 to keep the projecting shape.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A film deposition device comprising:
a chamber;
a mounting part provided in the chamber to allow a substrate to be placed thereon and containing aluminum nitride;
a heater provided in the mounting part;
a supply part configured to supply a process gas for film deposition to the substrate on the mounting part in the chamber; and
a cover film covering a mounting surface of the mounting part on which the substrate is placed, a back surface opposite to the mounting surface, and a side surface between the mounting surface and the back surface and containing yttrium oxide.

2. The device of claim 1, wherein the cover film contains Y₂O₃ or YOF.

3. The device of claim 1, wherein a thickness of the cover film is 0.5 μm or more and less than 10 μm.

4. The device of claim 1, wherein the cover film covers the mounting surface, the back surface, and the side surface of the mounting part with a substantially uniform thickness.

5. The device of claim 1, wherein the cover film covering the mounting surface is a laminated film of a first cover film and a second cover film.

6. The device of claim 5, wherein the first and second cover films each contain Y₂O₃ or YOF.

7. The device of claim 5, wherein the cover film covering the mounting surface is thicker than the cover film covering the back surface or the side surface.

8. The device of claim 5, wherein a total thickness of the first and second cover films forming the laminated film exceeds 1 μm and is 25 μm or less.

9. The device of claim 1, wherein a value of a ratio (P2/P1) of an intensity peak P2 of an X-ray diffraction spectrum of a material of the cover film to an intensity peak P1 of an X-ray diffraction spectrum of a material of the mounting part is 0.1 or more.

10. The device of claim 5, wherein a value of a ratio (P2/P1) of an intensity peak P2 of an X-ray diffraction spectrum of a material of the cover film to an intensity peak P1 of an X-ray diffraction spectrum of a material of the mounting part with regard to the cover film covering the mounting surface is 0.1 or more and is larger than the value with regard to the cover film covering the back surface or the side surface.

11. The device of claim 1, wherein the supply part is configured to further supply a cleaning gas for cleaning inside of the chamber into the chamber.

12. The device of claim 1, wherein the mounting surface of the mounting part has a plurality of convex portions.

13. A substrate support device comprising:
a mounting part to be provided in a chamber of a film deposition device to allow a substrate to be placed thereon, the mounting part containing aluminum nitride;
a heater provided in the mounting part; and
a cover film covering a mounting surface of the mounting part on which the substrate is placed, a back surface opposite to the mounting surface, and a side surface between the mounting surface and the back surface and containing yttrium oxide.

14. The device of claim 13, wherein the cover film contains Y₂O₃ or YOF.

15. The device of claim 13, wherein a thickness of the cover film is 0.5 μm or more and less than 10 μm.

16. The device of claim 13, wherein the cover film covers the mounting surface, the back surface, and the side surface of the mounting part with a substantially uniform thickness.

17. The device of claim 13, wherein the cover film covering the mounting surface is a laminated film of a first cover film and a second cover film.

18. The device of claim 17, wherein the first and second cover films each contain Y₂O₃ or YOF.

19. The device of claim 13, wherein a value of a ratio (P2/P1) of an intensity peak P2 of an X-ray diffraction spectrum of a material of the cover film to an intensity peak P1 of an X-ray diffraction spectrum of a material of the mounting part is 0.1 or more.

20. The device of claim 13, wherein the mounting surface of the mounting part has a plurality of convex portions.
